(19) United States
(12) Patent Application Publication
(10) Pub. No.: US 2008/0121422 A1
(43) Pub. Date: May 29, 2008

(54) MULTILAYERED PRINTED-WIRING BOARD AND INTER-LAYER CONNECTING METHOD THEREOF

(75) Inventors: Jun Karasawa, Tokyo (JP); Terunari Kano, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 11/947,640

(22) Filed: Nov. 29, 2007

(30) Foreign Application Priority Data
Nov. 29, 2006 (JP) 2006-321972

(51) Int. Cl. H05K 1/11

(52) U.S. Cl. 174/262

(57) ABSTRACT

According to one embodiment, there is provided a multilayered printed-wiring board, which includes a first wiring layer and a second wiring layer each of which forms an outer layer, a plurality of third wiring layers which are disposed between the first wiring layer and the second wiring layer to form an inner layer structure, first vias disposed in the first and second wiring layers, second vias disposed in the third wiring layers and connected to the first vias, and a third via disposed in an innermost third wiring layer in the inner layer structure and connected to the second vias, the third via having a diameter larger than those of the first and second vias.

### CROSS-REFERENCE TO RELATED APPLICATIONS

This application is based upon and claims the benefit of priority from Japanese Patent Application No. 2006-321972, filed Nov. 29, 2006, the entire contents of which are incorporated herein by reference.

### BACKGROUND

1. Field

One embodiment of the present invention relates to a multilayered printed-wiring board configured to be used as a circuit board in an electronic equipment and an inter-layer connecting method of the wiring board.

2. Description of the Related Art

In the multilayered printed-wiring board used as the circuit board in the electronic equipment, a plated though-hole and a via having a via-hole filled with a conductive material such as metal are used frequently. The plated through-hole is mainly applied to connect together all wiring layers in the wiring board, and the via is mainly applied to connect adjacent two wiring layers. The plated through-hole is formed by applying a conductor plating process (for example, copper plating process) to an inside wall of a through-hole formed throughout the all wiring layers in the wiring board. Therefore, when the number of wiring layers stacked in the printed-wiring board increases, an uneven plating is frequently formed in a plated metal film plated on the inside wall of the through-hole, thereby resulting the increase of a following problem. The generation of the plating spot or the macle of this kind poses the breaking down of the plated metal film due to a crack of the plated metal in the through-hole caused by a thermal stress, an external mechanical stress, etc, applied to the wiring board. Accordingly, in a high-density multilayered printed-wiring board formed of, for instance, eight wiring layers, an inter-layer connecting technique with high connection reliability is required for the thermal stress and the external mechanical stress generated also in manufacturing the wiring board. As to such technique forming a via under consideration of the connection reliability, there is a technique which makes a bottom diameter of a via to be formed on a lid plating layer larger than that of an upper via to be formed just above the via. For example, Jpn. Pat. Appln. KOKAI Publication No. 2006-216713 discloses the description in relation to the above-mentioned technique.

In the multilayered printed-wiring board, to intend an inter-layer connection with high connection reliability against the thermal stress and the external mechanical stress generated also in manufacturing process of the wiring board, it is made an attempt at an inter-layer connection technique connecting the wiring layers in the multilayered printed-wiring board by means of the vias instead of the plated through-hole. In the case of the connection of all the wiring layers of the multilayered printed-wiring board by the vias, however, in a thermal cycle test, partial weakness of a layered structure, in which stress in a discrete direction caused by thermal expansion of a wiring of the wiring layers is concentrated to a via positioned at a center portion in the thickness direction of the stacked wiring layers under a high-temperature environment, is recognized.

The invention provides a multilayered printed-wiring board, comprising a first wiring layer and a second wiring layer each of which forms an outer layer; a plurality of third wiring layers which are disposed between the first wiring layer and the second wiring layer to form an inner layer structure; first vias disposed in the first and second wiring layers; second vias disposed in the third wiring layers and connected to the first vias; and a third via disposed in an innermost third wiring layer in the inner layer structure and connected to the second vias, the third via having a diameter larger than those of the first and second vias.

The invention provides an inter-layer connecting method of a multilayered printed-wiring board, comprising disposing a via at a part of each of wiring layers which compose the multilayered printed-wiring board; and making a diameter of a center via positioned in an innermost wiring layer larger than those of vias positioned in other wiring layers so that the wiring layers in the wiring board are connected with each other through the vias.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a sectional side view illustrating a configuration of an electronic equipment in which a circuit board structured by a multilayered printed-wiring board according to a first embodiment of the invention is used;

FIG. 2 is a sectional view illustrating an inter-layer connecting structure of the multilayered printed-wiring board according to the first embodiment of the invention;

FIG. 3 is a sectional view illustrating an inter-layer connecting structure of a multilayered printed-wiring board according to a second embodiment of the invention;

FIG. 4 is a sectional view illustrating an inter-layer connecting structure of a multilayered printed-wiring board according to a third embodiment of the invention;

FIG. 5 is a perspective view illustrating another structure of a composite via disposed in an inter-layer connecting section according to the third embodiment of the invention;

FIG. 6 is a perspective view illustrating a further structure of the composite via disposed in the inter-layer connecting section according to the third embodiment of the invention;

FIG. 7A is a sectional view illustrating an inter-layer connecting structure of a multilayered printed-wiring board according to a fourth embodiment of the invention; and

FIG. 7B is a perspective view illustrating another structure of a composite via of a multilayered printed-wiring board according to the fourth embodiment.

### DETAILED DESCRIPTION

Various embodiments according to the invention will be described hereinafter with reference to the accompanying drawings. In general, according to one embodiment of the invention, hereinafter, embodiments of the present invention will be described with reference to the drawings.

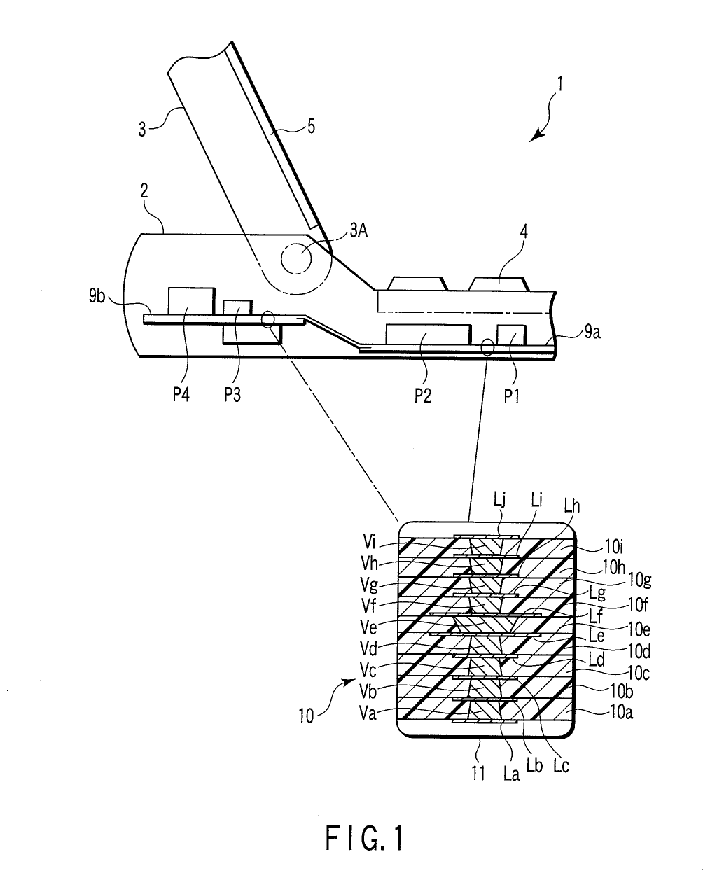

FIG. 1 shows a structure of an electronic equipment using a multilayered printed-wiring board according to an embodiment of the invention.

In an electronic equipment 1 shown in FIG. 1, a display housing 3 is mounted to a main body 2 by means of a hinge mechanism 3A so that the housing 3 can be tilted with respect to the main body 2. The main body 2 is provided with an operation unit such as a pointing device (not shown) and a keyboard 4. The housing 3 is provided with a display device 5 such as an LCD.

Circuit boards 9a and 9b with circuit parts P1, P2, P3, P4 mounted thereon are disposed inside the main body 2. The circuit boards 9a, 9b are each composed of multilayered printed-wiring board 10 prepared in accordance with the embodiments of the invention. The wiring board 10 has an inter-layer connecting section 11 at which whole wiring layers in the wiring board 10 are connected together by vias. Wiring patterns provided on each wiring layer are mutually connected with another layers through the connecting section 11. For example, the connecting section 11 is applied to connect mutually power source patterns of each wiring layer, to connect mutually grounding patterns of each wiring layer, and to connect mutually specific signal patterns of arbitrary wiring layers, etc.

The connecting section 11 is formed by arranging vias provided in each of the wiring layers in a manner that the vias are continuously connected together in a layer stacking direction through lands in a predetermined area of each wiring layer in the wiring board 10.

The multilayered printed-wiring board 10 is composed by stacking between a lowermost wiring layer or a first wiring layer 10a and an uppermost wiring layer or a second wiring layer 10i forming outer layers, a plurality of (7 layers in this case) inner wiring layers or third wiring layers 10b, 10c, 10d, 10e, 10f, 10g and 10h stacked in the order mentioned. Among inner third wiring layers 10b to 10h, the wiring layer 10e is the innermost layer in the stacking direction of the wiring board 10. Not shown in the figure, each of the wiring layers 10a to 10i is made of an insulating material layer with electric wiring patterns formed thereon to form a wiring layer.

The connecting section 11 is structured in a manner that the first vias Va and Vi are respectively disposed in the first and second wiring layers 10a and 10i forming outer layers, second vias Vb, Vc, Vd and Vh, Vg, Vf are disposed in third wiring layers 10b to 10d and 10h to 10f, respectively, in such a manner that the vias Va to Vd and vias Vi to Vf are continuously connected, respectively, and a third via Ve which is disposed in the third wiring layer 10e as the innermost wiring layer which has a larger diameter than those of the first vias Va and Vi as well as the second vias Vb to Vh and is continuously connected with the another vias Vd and Vf in the stacking direction so that the vias Va to Vi are straightly connected through all the wiring layers 10a to 10i through respective lands La to Lj. Depending on the difference between a diameter of the via Ve and those of the vias Va to Vd and Vf to Vi, lands Le and Lf disposed at both ends of the third via Ve have larger diameters than those of the lands La to Ld and Lg to Lj disposed at the first and second vias Va to Vd and Vf to Vi. That is to say, third via Ve and lands Le and Lf disposed at both ends of the via Ve have larger connecting areas than those of the remaining vias and the corresponding lands. Each of the vias Va to Vi is formed by filling with a conductive material such as copper into a via-hole formed in each of the wiring layers 10a to 10i so that the vias Va to Vi are continuously connected in the layer stacking direction of the layers 10a to 10i between the lands La and Lj, to form a conductive thick wiring structure at the inter-layer connecting section 11 with extremely low in electric resistance and large in electric current capacity.

In the inter-layer connecting section 11 in which all the layers 10a to 10i are connected together by the vias Va to Vi, the via Ve disposed in the innermost wiring layer 10e has a diameter larger than those of other remaining vias to enhance a connecting strength at a center portion of the stacked wiring layers, thereby enabling the inter-layer connection of the multilayered printed-wiring board get the high connection reliability even under the high-temperature environment. A high density multilayered printed-wiring board may be manufactured with a high yield.

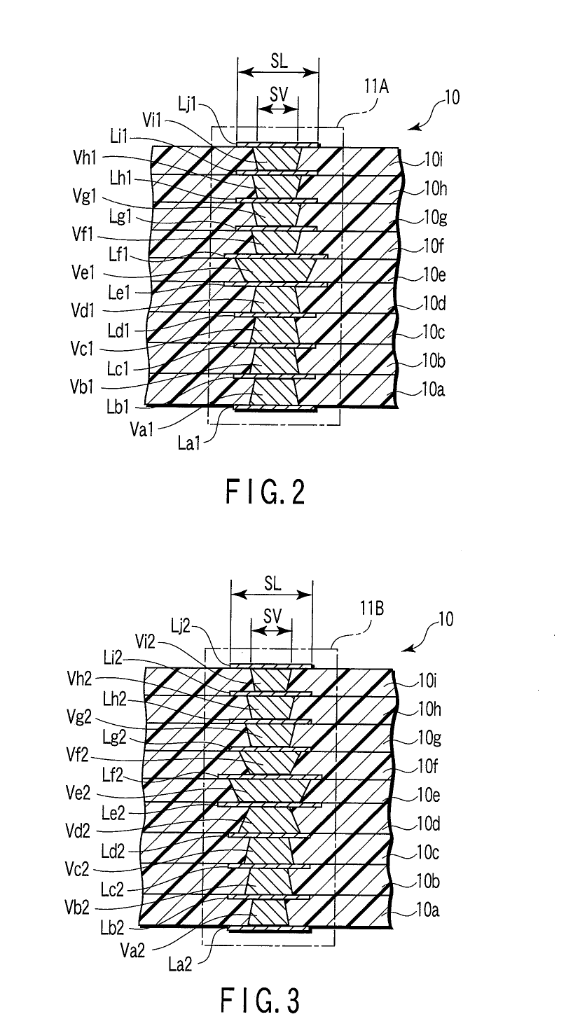

The configuration of the inter-layer connection structure of the multilayered printed-wiring board according to the first embodiment of the invention shown in FIG. 1 will be described in more detail by referring to FIG. 2, in which the vias are denoted by reference characters Va1 to Vi1 for those Va to Vi shown in FIG. 1.

In the wiring board 10 shown in FIG. 2 according to the first embodiment of the invention, each via except for the via Ve1 positioned in the innermost layer 10e has the identical diameter, and the via Ve1 positioned in the innermost layer 10e has a diameter larger than those of other vias in the connecting section 11A connecting all the layers 10a to 10i by the vias Va1 to Vi1.

The wiring board 10 is composed of stacked wiring layers 10a to 10i. The wiring board 10 has the inter-layer connecting section 11A which connects all the layers 10a to 10i by the vias Va1 to Vi1.

The connecting section 11A is formed by continuously connecting in the stacking direction the vias Va1 to Vi1 disposed in all the layers 10a to 10i. Vias Va1 to Vi1 are associated with lands La1 to Lj1, respectively. Each of the lands except for the lands Le1 and Lf1 provided with respect to the innermost via Ve1 is structured to have a diameter SL larger than a diameter SV of opening faces of each of the vias except for the innermost via Ve1, so that the opening faces thereof are blocked. The opening faces of the innermost via Ve1 are blocked by the lands Le1 and Lf1 each having a diameter larger than those of the lands having the diameter SL. Accordingly, the vias Va1 to Vi1 are mutually connected and joined through the lands La1 to Lj1, respectively, so that the vias are continuously connected in the stacked direction across all the layers 10a to 10i.

Among each of vias Va1 to Vi1, via Ve1 disposed in the wiring layer 10e forming the innermost layer is structured to have a diameter larger than that of vias Va1 to Vd1, and Vf1 to Vi1 disposed in the wiring layers 10a to 10d and 10f to 10i. As mentioned earlier, lands Le1 and Lf1 are also structured to have diameters larger than those of lands La1 to Ld1 and Lg1 to Lj1 disposed at each of vias Va1 to Vd1 and Vf1 to Vi1, respectively.

Like this, in the wiring board 10 according to the first embodiment of the invention, each of vias Va1 to Vd1 and Vf1 to Vi1 has the same diameter except for the via Ve1 positioned at the innermost layer 10e, via Ve1 positioned at the innermost layer 10e has a larger diameter than each of other vias Va1 to Vd1 and Vf1 to Vi1, and then, enhances a connecting strength (adhesive force) with respect to via Ve1 positioned at the stacking center portion in comparison to that of each of other vias Va1 to Vd1 and Vf1 to Vi1 piled up to via Ve1.

Vias Va1 and Vi1 disposed in the outermost wiring layers (first and second wiring layers) 10a and 10i acting as outer layers may not be a solid structure having via-holes each filled with a conductive material, but they may each have open shapes of recessed cross sections by depositing on the inner side walls of via-holes conductive layers. The diameters of the vias Va1 and Vi1 may be arbitrarily determined regardless of diameters of the vias in other layers piled up in the wiring board.

As mentioned above, the multilayered printed-wiring board having the inter-layer connecting section by piling up the vias with connecting strengths sufficiently sustainable against the stress concentrating to the center portion of the stacked layers, and make it possible to achieve the inter-layer connection with high connection reliability, and also to achieve further multiple layering of the printed-wiring board. The manufacturing of the high-density and multilayered printed-wiring board may be actualized with the high yield.

FIG. 3 shows the inter-layer connection structure of the multilayered printed-wiring board according to the second embodiment of the invention. The multilayered printed-wiring board 10 of the second embodiment has a feature to have a via arrangement in which, in an inter-layer connecting section 11B connecting all the layers by vias including a via positioned in the innermost layer having the largest diameter, and the diameters of the other vias are made gradually larger toward the innermost layer as shown in FIG. 3. In the second embodiment, each via diameter (diameter of opening face of via: SV) and each land diameter SL are made different, respectively, for each layer.

The wiring board 10 is, in a similar way in the first embodiment, composed of the wiring layers 10a to 10i. The wiring board 10 has an inter-layer connecting section 11B which connects all the layers by the vias.

The connecting section 11B is formed by continuously connecting in the stacking direction vias Va2 to Vi2 disposed for each layer so that the vias are connected straightly through all the layers. Each of vias Va2 to Vi2 has lands La2 to Lj2, respectively. Each of lands La2 to Lj2 is structured to have the diameter SL larger than the diameter SV of each opening surface of the via so as to block the face of the vias, respectively. Each of vias Va2 to Vi2 is mutually connected through lands La2 to Li2 in the stacking direction across all the layers.

Each of vias Va2 to Vi2 has different diameter so that the stresses to be concentrated toward the innermost layer is distributed to each of the connecting portions between the respective vias. In the second embodiment, among each of vias Va2 to Vi2 piled up in the connecting section 11B, the diameter of via Ve2 disposed in the wiring layer 10e forming the innermost layer has the largest diameter, and the diameters of other vias Va2 to Vd2 and Vf2 to Vi2 are made gradually (continuously for each layer in the embodiment) larger from the outermost layers to the innermost layer, respectively. In other words, the diameter of via Ve2 provided for the wiring layer 10e forming the innermost layer has the largest diameter, and the diameter of each via becomes gradually smaller when going toward the outermost layers.

Such connecting section 11B formed by piling up the vias differing in diameter from one another receives the stress to be concentrated toward the stacked center as the distributed stress to be applied to the connecting faces of the vias for each layer, and then, the connecting section 11B distributes the excess stress concentration applied to the via at the center portion under the high-temperature environment and may improve the connection reliability of the vias.

Thereby, as given above, the second embodiment may form the inter-layer connecting section by piling up the vias with the connecting strength capable of being sufficiently sustainable against the stress to be concentrated to the center portion under the high-temperature environment, and may provide the multilayered printed-wiring board capable of achieving the inter-layer connection with high connection reliability. The second embodiment can manufacture the wiring board with high-density with the high yield.

In the second embodiment given above, although the respective vias Va2 to Vi2 have diameters different from one another for each layer, in a multilayered printed-wiring board stacked, for example, by 12 wiring layers or more, a piled-up structure, which gradually (for example, for every two layers) differs in the diameters in a plurality of wiring layers, is a possible approach. Vias Va1 and Vi1 disposed in the wiring layers (first and second wiring layers) 10a, 10i forming the outermost layers may not be of a solid structure but may each have shapes of recessed cross sections by depositing conductive material applied on inner walls of via-holes, for example. The sizes of the diameters of these vias in the outermost layers also may be arbitrarily determined regardless of the diameters of the vias in the other layers piled up in the board.

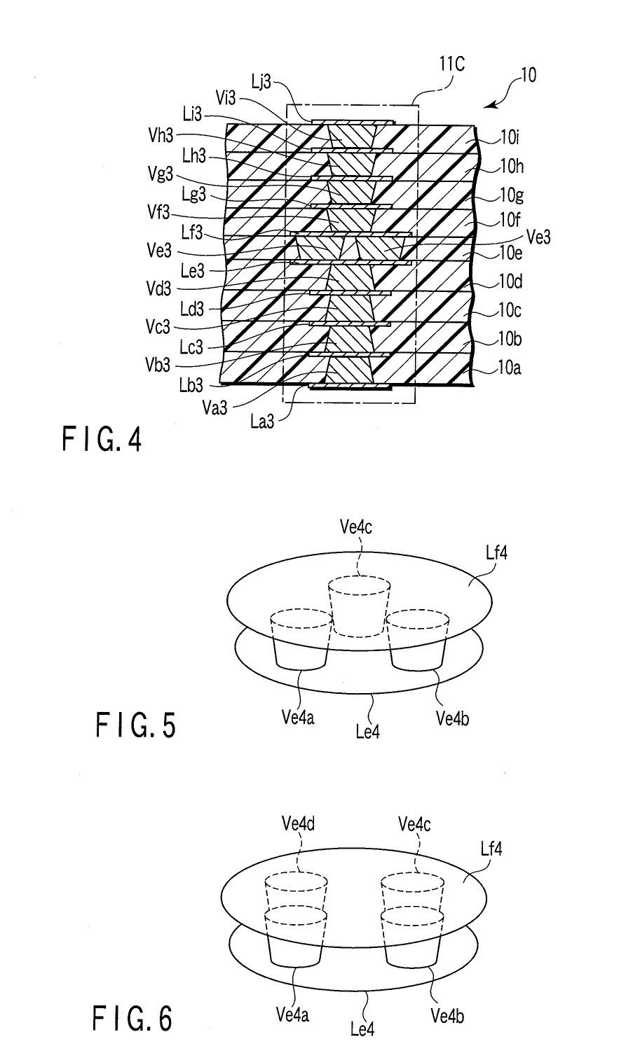

FIG. 4 depicts an inter-layer connection section structure 11C of a multilayered printed-wiring board 10 according to the third embodiment. In the multilayered printed-wiring board 10 regarding the third embodiment, the structure of the via positioned in the innermost layer among vias piled up for each layer is formed of a plurality of vias joined on the same plane of a land in an inter-layer connecting section 11C which connects all the layers 10a to 10i by the vias Va3 to Vi3. The lands Le3 and Lf3 to which the plurality of (two, in this case) vias Ve3a and Ve3b are joined each has a larger diameter than those of the lands of the other vias Va3 to Vd3 and Vf3 to Vi3.

In the similar manners as the above described first and the second embodiments, the wiring board 10 is composed of piled up wiring layers 10a to 10i. The wiring board 10 has the inter-layer connecting section 11C in which all the layers 10a to 10i are connected with the vias Va3 to Vi3.

The connecting section 11C is formed by continuously connecting vias Va3 to Vi3 disposed for each layer in a stacking direction so that the vias are provided through all the layers 10a to 10i. The respective vias Va3 to Vi3 have lands La3 to Lj3, respectively. Each of vias Va3 to Vi3 is connected with one another through lands la3 to Lj3, respectively, and continuously connected in a stacking direction across all the layers 10a to 10i.

Among the foregoing stacked wiring layers 10a to 10i, the wiring layer 10e forming the innermost layer is structured in a via structure by connecting two vias Ve3a and Ve3b by putting them side by side between lands Le3 and Lf3. This via structure is referred to as composite vias. Lands Le3 and Lf3 joined with the composite vias Ve3a and Ve3b are structured in the innermost layer 10e so as to have diameters larger than that of each of vias Va3 to Vd3 and Vf3 to Vi3 each disposed in the wiring layers 10a to 10d and 10f to 10i, and larger than that of each of lands La3 to Ld3 and Lg3 to Lj3. Thereby, the connecting section 11C enhances the connecting strength of the composite vias ve3a and ve3b positioned at the center portion with respect to vias Va3 to Vd3 and Vf3 to Vi3 piled up on both sides of the composite vias Ve3a and Ve3b.

The composite via structure formed of vias Ve3a and Ve3b given above has a via structure connecting in a parallel manner the two vias Ve3a and Ve3b arranged side by side between lands Le3 and Lf3. Further, FIGS. 5 and 6 illustrate examples of the another composite vias structures, respectively.

The composite via structure shown in FIG. 5 has a structure in which three vias are arranged in a triangle shape between two lands. In FIG. 5, three vias Ve4a, Ve4b and Ve4c are arranged and joined between two lands Le4 (equivalent to land Le3 in FIG. 4) and Lf4 (equivalent to land Lf3 in FIG. 4).

A composite via structure shown in FIG. 6 has a via structure in which four vias are arranged in a square shape between lands Le4 and Lf4. As shown in the figure, the via structure in which four vias Ve4a, Ve4b, Ve4c, Ve4d are arranged between two lands Le4 and Lf4.

As mentioned above, since the connecting section 11C formed by disposing the composite vias in the innermost layer and piling up vias for each layer has a connecting strength sufficiently sustainable to the stress to be concentrated toward a center portion under a high-temperature environment, a multilayered printed-wiring board which makes it possible to achieve an inter-layer connection with high connection reliability may be fabricated. Manufacturing of a multilayered high density wiring board with a high yield may be realized.

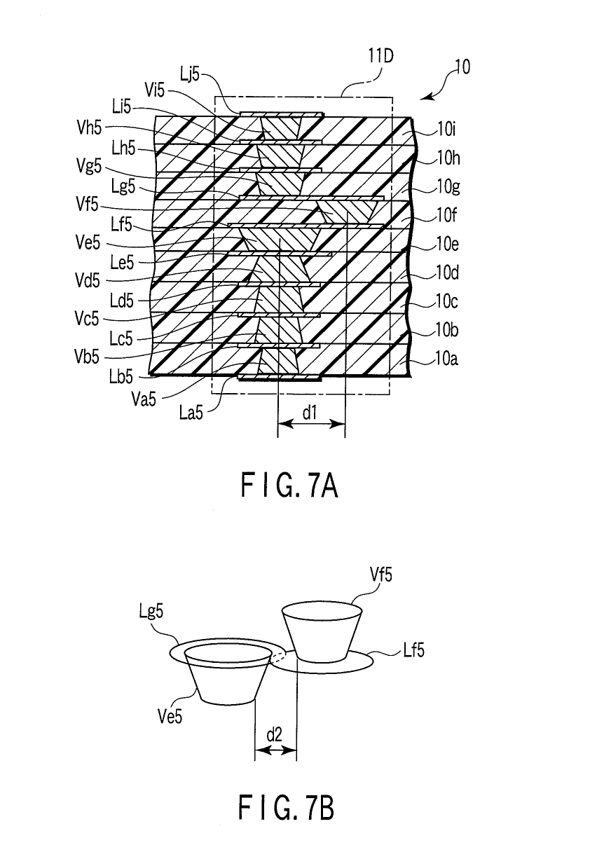

FIGS. 7A and 7B depict an inter-layer connection structure of a multilayered printed-wiring board according to the fourth embodiment. The multilayered printed-wiring board 10 regarding the fourth embodiment is formed, as depicted in FIG. 7A, by continuously connecting vias Va5 to Vi5 disposed for each layer in a stacking direction of the wiring layers 10a to 10i. Each of vias Va5 to Vi5 have lands La5 to Lj5, respectively.

The wiring board 10 regarding the fourth embodiment has a via structure, in a similar way as the second embodiment, to set the diameter of the via Ve5 positioned in the innermost layer among the vias Va5 to Vi5 piled up for each layer to the largest one and to set the diameters of other vias so as to be gradually increased toward the innermost layer 10e in an inter-layer connecting section 11D connecting all the layers 10a to 10i by vias, except for one of the piled vias is biased or offset in position by utilizing two lands. In the fourth embodiment of FIG. 7A and 7B, a biasing quantity offset distance d1 of the via to be biased (Vf5 in the embodiment) among each of vias Va5 to Vi5 limited within a fixed range (for example, 50 μm) under consideration of a manufacturing error range. As shown in FIG. 7B, under a condition that a part of lands Lf5 and Lg5 are overlapped to one another in a distance d2 between the via Vf5 to be biased and the via Ve5 to be adjacently piled up to the via Vf5 to be biased, the bias of the particular via is allowed. Such connecting section 11D may be used as a means for improving in a freedom of pattern designing in providing an inter-layer connecting section formed by piling up the vias, for example.

In the multilayered printed-wiring board according to the foregoing embodiments, applying a wiring layer made of a material of low linear coefficient of thermal expansion, a wiring layer made of a material of low Young's modulus, a wiring layer made of a material of a high glass-transfer temperature, etc., to the wiring layer forming the innermost layer (10e in each embodiment described above) enables to improve the connection reliability of the inter-layer connecting section in the wiring board.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multilayered printed-wiring board, comprising:
a first wiring layer and a second wiring layer, said first and second wiring layers forming an outer layer;
a plurality of third wiring layers that are disposed between the first wiring layer and the second wiring layer to form an inner layer structure;
a plurality of first vias disposed in the first and second wiring layers;
a plurality of second vias disposed in the third wiring layers and connected to the first vias; and
a third via disposed in an innermost third wiring layer in the inner layer structure and connected to the second vias, the third via having a diameter larger than those of the first and second vias.

2. The multilayered printed-wiring board according to claim 1, wherein each of the first to third vias has a land through which the vias are connected through the printed-wiring board.

3. The multilayered printed-wiring board according to claim 2, wherein each of the vias is arranged in each of the wiring layers so as to be connected through all the wiring layers.

4. The multilayered printed-wiring board according to claim 2, wherein each of the vias has a diameter gradually increasing toward the innermost wiring layer.

5. The multilayered printed-wiring board according to claim 2, wherein each of the second vias has a diameter larger than those of the first vias and smaller than that of the third via.

6. The multilayered printed-wiring board according to claim 2, wherein the second vias have a diameter gradually increasing toward the third via.

7. The multilayered printed-wiring board according to claim 1, wherein the second vias and the third via are filled vias.

8. The multilayered printed-wiring board according to claim 2, wherein at least some parts of each of the continuously connected vias are overlapped with each other in a stacking direction of the wiring layers.

9. The multilayered printed-wiring board according to claim 2, wherein the third via is formed of a multi-via structure in which a plurality of vias are connected in parallel to a plane of a land associated with the third via, and the land with the plurality of vias connected thereto has a diameter larger than those of lands associated with the first and second vias.

10. An inter-layer connecting method of a multilayered printed-wiring board, comprising:
disposing a via at a part of each of wiring layers that comprise the multilayered printed-wiring board; and
making a center via positioned in an innermost wiring layer with a diameter larger than those of vias positioned in other wiring layers so that the wiring layers in the wiring board are connected with each other through the vias.
